(19) United States
(12) Patent Application Publication
(10) Pub. No.: US 2025/0264540 A1
(43) Pub. Date: Aug. 21, 2025

(54) BATTERY MONITORING DEVICE

(71) Applicant: DENSO CORPORATION, Kariya-city (JP)

(72) Inventor: Kazutaka HONDA, Kariya-city (JP)

(21) Appl. No.: 19/198,545

(22) Filed: May 5, 2025

Related U.S. Application Data
(63) Continuation of application No. PCT/JP2023/036742, filed on Oct. 10, 2023.

(30) Foreign Application Priority Data
Nov. 8, 2022 (JP) 2022-178858

(51) Int. Cl. G01R 31/3835; G01R 31/367; G01R 31/396

(52) U.S. Cl. CPC G01R 31/3835; G01R 31/367; G01R 31/396

(57) ABSTRACT

A detection controller controls the path switching unit and A/D converter in a battery monitoring device; and detects the respective voltages of the battery cells in a time-division manner based on a digital signal from the A/D converter. When detecting the voltage of a target battery cell, the detection controller controls to connect the detection path to the A/D converter. If the potential difference between the voltage of a present target battery cell and either the voltage of the target battery cell connected to the A/D converter by the detection path in the previous instance or the voltage at a predetermined point in the path switching unit and the A/D converter exceeds a predetermined threshold, a non-detection period is set before detecting the voltage of the present target battery cell. During this non-detection period, a non-detection path with a smaller time constant is connected to the A/D converter.

### CROSS REFERENCE TO RELATED APPLICATIONS

The present application is a continuation application of International Patent Application No. PCT/JP2023/036742 filed on Oct. 10, 2023, which designated the U.S. and claims the benefit of priority from Japanese Patent Application No. 2022-178858 filed on Nov. 8, 2022. The entire disclosures of all of the above applications are incorporated herein by reference.

### TECHNICAL FIELD

The present disclosure relates to a battery monitoring device.

### BACKGROUND

A battery monitoring device may monitor a battery pack in which battery cells are connected in series.

### SUMMARY

The present disclosure describes a battery monitoring device that monitors a battery pack in which battery cells are connected in series, and describes that the battery monitoring device includes a voltage detector and a filter.

### BRIEF DESCRIPTION OF DRAWINGS

Objects, features and advantages of the present disclosure will become more apparent from the following detailed description made with reference to the accompanying drawings. In the drawings:

FIG. 1 is a diagram schematically showing the configuration of a battery monitoring device according to a first embodiment;

FIG. 2 is a diagram for explaining an example of a series of operations performed by a battery monitoring IC during voltage detection according to the first embodiment;

FIG. 3 is a diagram for explaining an example of a series of operations performed by a battery monitoring IC during voltage detection according to a comparative example;

FIG. 4 is a diagram showing a circuit configuration on a path from a predetermined battery cell to an ADC when detecting the voltage of the specific battery cell in a comparative example;

FIG. 5 is a diagram illustrating an example of charging/discharging characteristics in a path that passes through a filter and a path that does not pass through a filter according to the first embodiment and a comparative example;

FIG. 6 is a diagram showing a circuit configuration on a path from a predetermined battery cell to an ADC when detecting the voltage of the specific battery cell according to the first embodiment; and

FIG. 7 is a diagram schematically showing the configuration of a battery monitoring device according to a second embodiment.

### DETAILED DESCRIPTION

A battery monitoring device may include a multiplexer and one A/D converter, and may use the A/D converter to detect the voltages of multiple battery cells by A/D conversion in a time-division manner. The A/D converter may also be referred to as an ADC and an analog-to-digital converter in the present disclosure. The battery monitoring device having the above configuration may be provided with a filter that is interposed in series with the detection path that is connected to both terminals of each of the multiple battery cells. In this case, the filter may be a low-pass filter made up of a resistor with a relatively high resistance value and a capacitor in order to achieve the function of removing noise superimposed on the battery cell.

In a comparative example, when the common voltage of the battery cell being detected fluctuates significantly, such as during the initial voltage detection or especially when the detection target switches from the top battery cell to the bottom battery cell, a current that causes an error may flow in the filter due to the discharge of charge caused by the initialization of the multiplexer, resulting in a voltage detection error. Therefore, if it were possible to arbitrarily select a battery cell to be detected among battery cells, an initial waiting would be required, and the logic would become more complex.

As a countermeasure to this issue, it may be possible to provide a pyramid sampling method in which the detection target is switched in sequence from the lowermost battery cell to the uppermost battery cell, and then switched in sequence from the uppermost battery cell to the lowest battery cell. However, even in a configuration that adopts such a method, if the initial detection target is not the lowermost battery cell but an upper-level battery cell, the issue of voltage detection error occurring during initial voltage detection may not be resolved.

According to an aspect of the present disclosure, a battery monitoring device monitors a battery pack in which battery cells are connected in series. The battery monitoring device includes a voltage detector and a filter. The voltage detector detects respective voltages of the battery cells through a detection path that is connected to both ends of each of the battery cells. The filter is adapted to each of the battery cells, and the filter is connected in series to the detection path. The voltage detector includes an analog-to-digital converter, a path switchover unit, and a detection controller. The analog-to-digital converter executes analog-to-digital conversion on target detection voltages corresponding to the respective voltages of the battery cells. The path switchover unit switches a path connected to the analog-to-digital converter. The detection controller controls an operation of the path switchover unit and an operation of the analog-to-digital converter; and detects the respective voltages of the battery cells in a time-division manner based on a digital signal output from the analog-to-digital converter. The detection controller controls the operation of the path switchover unit such that the detection path corresponding to a target battery cell is connected to the analog-to-digital converter, in a case of detecting a voltage of the target battery cell being a battery cell to be detected among the battery cells; and sets a non-detection period during which a non-detection path is connected to the analog-to-digital converter before detecting a first voltage, in a case where a potential difference between the first voltage and a second voltage is equal to or higher than a predetermined threshold. The first voltage is a voltage of a present target battery cell being a battery cell to be detected in a present time among the battery cells. The second voltage is either a voltage of a previous target battery cell being a battery cell connected to the analog-to-digital converter by the detection path in a previous time among the battery cells, or a voltage at a predetermined location in the path switchover unit and the analog-to-digital converter in an initial state. The non-detection path has a smaller time constant than the detection path.

When detecting the voltage of a target battery cell, which is a battery cell to be detected among the multiple battery cells, the detection controller controls the operation of the path switchover unit so that the detection path corresponding to the target battery cell is connected to the A/D converter. In addition, when the potential difference between the voltage of the present target battery cell and the voltage of the target battery cell connected to the A/D converter by the previous detection path or the voltage at a predetermined location in the path switchover unit and the A/D converter in an initial state becomes equal to or greater than a predetermined threshold, the detection control unit sets a non-detection period, which is a period during which the operation of the path switchover unit is controlled so that the non-detection path is connected to the A/D converter before detecting the voltage of the present target battery cell. The non-detection path has a smaller time constant than the detection path.

According to this configuration, a non-detection period is provided when the common voltage of the battery cell being detected fluctuates significantly, such as during the initial voltage detection or when the detection target is switched from the top battery cell to the bottom battery cell. Therefore, according to the above configuration, in such a case, the electric charge that would cause an error in voltage detection is discharged via the non-detection path, thereby suppressing the occurrence of voltage detection errors. In this case, the non-detection path has a smaller time constant than the detection path, so the time required for discharging the charge, and therefore the non-detection period, can be kept relatively short. Therefore, the above configuration provides the excellent effect of improving the accuracy of voltage detection while suppressing an increase in the overall detection time required to detect the voltages of battery cells.

Hereinafter, multiple embodiments will be described with reference to the drawings. Hereinafter, in the respective embodiments, substantially the same configurations are denoted by identical symbols, and repetitive description will be omitted.

### First Embodiment

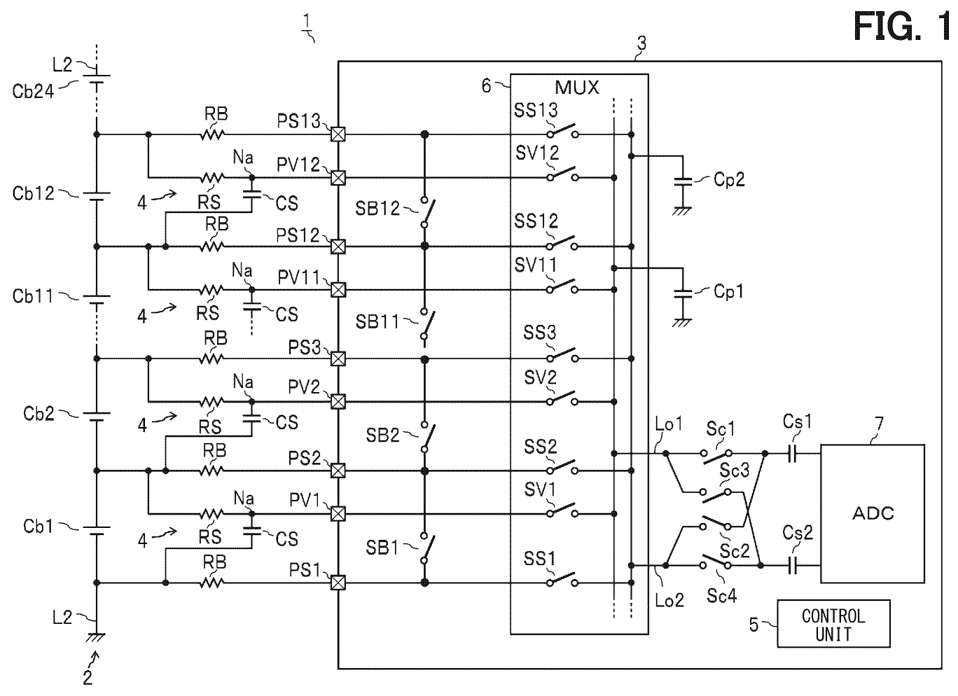

The first embodiment of the present disclosure is described with reference to FIGS. 1 to 6.

### Overall Configuration

As shown in FIG. 1, a battery monitoring device 1 according to this embodiment is mounted on a vehicle such as an automobile, and is a device that detects various states of a battery pack 2, such as the voltage of the battery pack 2, and monitors the state of the battery pack 2. The battery pack 2 may also be referred to as an assembled battery in this disclosure. The battery monitoring device 1 includes a battery monitoring IC 3, which is an integrated circuit in which circuits that perform various operations for battery monitoring are integrated, and external elements provided outside the battery monitoring IC 5. IC is an abbreviation for integrated circuit.

The battery pack 2 is mounted in a vehicle such as an automobile, for example, and has a configuration in which, for example, twenty four battery cells Cb are connected in series in multiple stages between a pair of DC power supply lines L1 and L2. In this case, the battery cell Cb is, for example, a secondary battery such as a lithium ion battery, a fuel cell, or the like. In addition, in FIG. 1, five battery cells Cb out of the twenty battery cells Cb are shown, and in order to distinguish these five battery cells Cb, numerals are appended to the end of the reference numerals.

This number corresponds to the arrangement of the battery cells Cb in the battery pack 2, with 1 being given to the battery cell Cb arranged on the lowest potential side, and with 2, 3, 4 and so on being given as it progresses toward the higher potential side, and with 24 being given to the battery cell Cb arranged on the highest potential side. Therefore, FIG. 1 shows battery cell Cb1 arranged on the lowest potential side, battery cell Cb2 arranged on the second lowest potential side, battery cell Cb11 arranged on the eleventh lowest potential side, battery cell Cb12 arranged on the twelfth lowest potential side, and battery cell Cb24 arranged on the highest potential side.

The components provided in the battery monitoring device 1 corresponding to each of the battery cells Cb1, Cb2, Cb11, and Cb12 among the above-mentioned battery cells Cb may also be distinguished by adding the same numbers to the end of the reference numerals. Here, in a case where there is no need to distinguish these configurations, the respective configurations will be collectively referred to by omitting the numbers at the ends. In the above configuration, a common mode voltage is superimposed on the battery cell Cb.

This common mode voltage becomes higher toward the battery cell Cb connected to the upper stage side of the the battery pack 2, that is, to the high potential side, and its maximum value is a relatively high voltage of about several hundred volts, for example. In this embodiment, for example, the common mode voltage of the battery cell Cb1 is 5V, the common mode voltage of the battery cell Cb12 is 60V, the common mode voltage of the battery cell Cb13 is 65V, and the common mode voltage of the battery cell Cb24 is 120V.

In the above configuration, of the twenty four battery cells Cb, the battery cells Cb1 to Cb12 arranged on the low potential side are collectively referred to as lower cells, and the battery cells Cb13 to Cb24 arranged on the high potential side are collectively referred to as upper cells. In this embodiment, of the various components of the battery monitoring device 1, only the components corresponding to the lower cells are described, and the description of the components corresponding to the upper cells is omitted, but the components corresponding to the upper cells are similar to the components corresponding to the lower cells.

### Configuration of External Element

First, the configuration of external elements provided outside the battery monitoring IC 3 will be described. The low potential terminal of the battery cell Cb13 and the high potential terminal of the battery cell Cb12 (not shown) are connected to a connection terminal PS13 via a resistor RB. A resistor RS and a capacitor CS are connected in series between the high potential terminal and the low potential terminal of the battery cell Cb12. A node Na, which is an interconnection node between the resistor RS and the capacitor CS, is connected to a connection terminal PV12. The low potential terminal of the battery cell Cb12 and the high potential terminal of the battery cell Cb11 are connected to a connection terminal PS12 via a resistor RB.

Although some of illustration is omitted, a resistor RS and a capacitor CS are connected in series between the high potential terminal and the low potential terminal of the battery cell Cb12. A node Na, which is an interconnection node between the resistor RS and the capacitor CS, is connected to a connection terminal PV11. Although not shown in the drawing, the low potential side terminal of the battery cell Cb11 and the high potential side terminal of the battery cell Cb10 (not shown) are connected to the connection terminal PS11 via the resistor RB.

The low potential terminal of the battery cell Cb3 and the high potential terminal of the battery cell Cb2 (not shown) are connected to a connection terminal PS3 via the resistor RB. The resistor RS and the capacitor CS are connected in series between the high potential terminal and the low potential terminal of the battery cell Cb2. The node Na, which is an interconnection node between the resistor RS and the capacitor CS, is connected to a connection terminal PV2.

The low potential terminal of the battery cell Cb2 and the high potential terminal of the battery cell Cb1 are connected to the connection terminal PS2 via the resistor RB. The resistor RS and the capacitor CS are connected in series between the high potential terminal and the low potential terminal of the battery cell Cb1. The node Na, which is an interconnection node between the resistor RS and the capacitor CS, is connected to a connection terminal PV1. The low potential terminal of the battery cell Cb1 is connected to the connection terminal PS1 via the resistor RB.

In the above configuration, the resistor RS and capacitor CS corresponding to each battery cell Cb included in the filter 4, which is a low-pass filter. That is, in the above configuration, the filter 4 are provided so as to correspond to the respective battery cells Cb. In this specification, the low-pass filter may be abbreviated as LPF. The resistor RB is a discharging resistor for discharging the battery cell Cb during equalization. Since the resistor RB functions as a current limiting resistor during equalization, the resistance value thereof is much smaller than the resistance value of the resistor RS included in the filter 4, specifically, for example, about several tens of ohms (Q).

### Internal Configuration of Battery Monitoring IC

Next, the internal configuration of the battery monitoring IC 3 will be described. The battery monitoring IC 3 functions as a voltage detection device or a voltage detector that detects the voltages of the multiple battery cells Cb via detection paths connected to both terminals of each of the multiple battery cells Cb. In the above configuration, the detection path corresponding to the battery cell Cb12 is a path through which a current flows in this order: the high potential terminal of the battery cell Cb12→resistor RS→connection terminal PV12→each circuit inside the battery monitoring IC 3→connection terminal PS12→resistor RB→low potential terminal of the battery cell Cb12.

In the above configuration, the detection path corresponding to the battery cell Cb11 is a path through which a current flows in this order: the high potential terminal of the battery cell Cb11→resistor RS→connection terminal PV11→each circuit inside the battery monitoring IC 3→connection terminal PS11→resistor RB→low potential terminal of the battery cell Cb11. In the above configuration, the detection path corresponding to the battery cell Cb2 is the path through which a current flows in this order: high potential terminal of the battery cell Cb2→resistor RS→connection terminal PV2→each circuit inside the battery monitoring IC 3→connection terminal PS2→resistor RB→low potential terminal of the battery cell Cb2.

In the above configuration, the detection path corresponding to the battery cell Cb1 is a path through whicha current flows in this order: high potential terminal of the battery cell Cb1→resistor RS→connection terminal PV1→each circuit inside the battery monitoring IC 3→connection terminal PS1→resistor RB→low potential terminal of the battery cell Cb1. In this manner, the battery monitoring IC 3 detects the voltages of the multiple battery cells Cb via a detection path that passes through the filter 4. In other words, in the above configuration, the filter 4 is provided so as to be interposed in series in the detection path.

The battery monitoring IC 3 includes a control unit 5. The control unit 5 may also be referred to as a controller in this disclosure. The control unit 5 includes a communication I/F for communication with the outside, a register for storing various data, and the like, and controls the overall operation of the battery monitoring IC 3. Note that I/F is an abbreviation for interface. The battery monitoring IC 3 also includes an equalization switch SB provided corresponding to each of the battery cells Cb for discharging the corresponding battery cell Cb. An equalization switch SB includes, for example, a MOS transistor, and constitutes a discharge circuit together with the resistor RB. On/off of the equalization switch SB is controlled by the control unit 5. In the equalization process, the operation of each discharge circuit is controlled so that the voltage of each battery cell Cb is approximately the same as the voltage of the lowermost battery cell Cb. A connection of the equalization switch SB is described as follows.

That is, the equalization switch SB12 corresponding to the battery cell Cb12 is connected between the connection terminal PS13 and the connection terminal PS12. Although some of the illustrations are omitted, the equalization switch SB11 corresponding to the battery cell Cb11 is connected between the connection terminal PS12 and the connection terminal PS11. The equalization switch SB2 corresponding to the battery cell Cb2 is connected between the connection terminal PS3 and the connection terminal PS2. The equalization switch SB1 corresponding to the battery cell Cb1 is connected between the connection terminal PS2 and the connection terminal PS1.

In the above configuration, the equalization path, which is the path through which current flows when the equalization switch SB connected in this manner discharges the battery cell Cb, is specifically as follows. That is, the equalization path corresponding to the battery cell Cb12 is a path through which a current flows in this order: high potential terminal of the battery cell Cb→resistor RB→connection terminal PS→equalization switch SB→connection terminal PS→resistor RB→low potential terminal of the battery cell Cb12. The equalization path corresponding to the battery cell Cb11 is a path through which a current flows in this order: high potential terminal of battery cell Cb11→resistor RB→connection terminal PS12→equalization switch SB11→connection terminal PS11→resistor RB→low potential terminal of battery cell Cb12.

The equalization path corresponding to the battery cell Cb2 is a path through which a current flows in this order: high potential terminal of the battery cell Cb2→resistor RB→connection terminal PS3→equalization switch SB2→connection terminal PS2→resistor RB→low potential terminal of the battery cell Cb2. The equalization path corresponding to the battery cell Cb1 is a path through which the current flows in this order: high potential terminal of the battery cell Cb1→resistor RB→connection terminal PS2→equalization switch SB1→connection terminal PS1 →resistor RB→low potential terminal of the battery cell Cb1. The equalization path is a path for discharging each of the multiple battery cells Cb, and corresponds to a non-detection path having a smaller time constant than the detection path.

The battery monitoring IC 3 includes a multiplexer 6, switches Sc1 to Sc4, capacitors Cs1 and Cs2, and an ADC 7 of a differential input type. In the following description and in FIG. 1, the multiplexer may be referred to as MUX. The MUX 6 includes switches SV corresponding to the connection terminals PV1 to PV12, respectively, and switches SS corresponding to the connection terminals PS1 to PS13, respectively. The switching element 40 includes, for example, a MOS transistor.

One terminal of each of the multiple switches SV is connected to a corresponding connection terminal PV. Specifically, one terminal of each of the switches SV12, SV11, SV2, and SV1 is connected to corresponding one of the connection terminals PV12, PV11, PV2, and PV1. The other terminal of each of the multiple switches SV is connected to a first output line Lo1. Specifically, the other terminals of the switches SV12, SV11, SV2, and SV1 are connected to the first output line Lo1.

One terminal of each of the multiple switches SS is connected to the corresponding connection terminal PS. Specifically, one terminal of each of the switches SS13, SS12, SS3, SS2, and SS1 is connected to corresponding one of the connection terminals PS13, PS12, PS3, PS2, and PS1. The other terminal of each of the multiple switches SS is connected to a second output line Lo2. Specifically, the other terminals of the switches SS13, SS12, SS3, SS2, and SS1 are connected to the second output line Lo2.

A parasitic capacitance Cp1 due to wiring exists between the first output line Lo1 and the ground to which the reference potential of the circuit is applied. A parasitic capacitance Cp2 due to wiring exists between the second output line Lo2 and ground. The MUX 6 receives the voltages of connection terminals PV1 to PV12 and PS1 to PS13, and selectively outputs one of the input voltages by switching switches SV and SS on and off. Such a selection operation by the MUX 6, that is, the switching on and off of the switches SV and SS, is controlled by the control unit 5.

The switches Sc1 to Sc4 and the capacitors Cs1 and Cs2, together with switches, capacitors, and a differential output type OP amplifier (not shown) provided in the stage preceding the ADC 7, are included in a differential sample-and-hold circuit. In this case, the sample-and-hold circuit also performs level shifting to step down a high common-mode voltage to a low common-mode voltage.

The pair of capacitors Cs1 and Cs2 in the differential configuration corresponds to a sampling capacitance and has the same capacitance value. The “same capacitance value” in the present application does not only refer to a situation where the capacitance values are exactly identical, but also refers to a situation where there is a slight difference in the capacitance values as long as an advantageous effect is attained. The switches Sc1 to Sc4 include, for example, MOS transistors, and the control unit 5 controls their on/off switching. The control unit 5 controls the switches Sc1 and Sc4 and the switches Sc2 and Sc3 to be turned on and off complementarily.

One terminal of the capacitor Cs1 is connected to a first output line Lo1 via a switch Sc1, and is connected to a second output line Lo2 via a switch Sc2. One terminal of the capacitor Cs2 is connected to the first output line Lo1 via a switch Sc3, and is also connected to the second output line Lo2 via a switch Sc4. The other terminals of the capacitors Cs1 and Cs2 are connected to an OP amplifier or the like provided in the preceding stage of the ADC 7. The OP amplifier may also be referred to as an operational amplifier in this disclosure.

The ADC 7 is a differential input type ADC, and its operation is controlled by the control unit 5. In this case, the ADC 7 may be of various types, such as a delta-sigma (ΔΣ) ADC. The ADC 7 performs A/D conversion on the voltage output from the MUX 6, that is, the voltage on the first output line Lo 1 and the voltage on the second output line Lo 2, and outputs the digital signal obtained as the conversion result to the control unit 5.

In the above configuration, the MUX 6 functions as a path switchover unit that switches the path connected to the ADC 7. In other words, in this embodiment, the path switchover unit has a single MUX 6, and as will be described in detail later, the single MUX 6 selects either the detection path or the non-detection path as the path to be connected to the ADC 7. It should be noted that “connected to the ADC 7” here means being connected to the ADC 7 via the MUX 6, the switches Sc1 to Sc4, and the capacitors Cs1 and Cs2.

When detecting the voltage of a target battery cell that is a battery cell to be detected among the multiple battery cells Cb, the MUX 6 can execute an operation of switching the path so that the detection path corresponding to the target battery cell is connected to the ADC 7. The MUX 6 can output only one voltage among the connection terminals PS1 to PS13. In other words, the MUX 6 is capable of executing a first switching operation for switching the path so that only one of the two terminals of the battery cell Cb is connected to the ADC 7. The path connected to the ADC 7 by the first switching operation is a part of the equalization path, and therefore corresponds to a non-detection path having a smaller time constant than the detection path, similar to the equalization path. The MUX 6 is capable of executing a second switching operation of switching the path so that the equalization path, which is a path for discharging each of the multiple battery cells Cb, is connected to the ADC 7.

In the above configuration, the following operation is performed during voltage detection, that is, when detecting the voltage of a target battery cell that is a detection target battery cell among the battery cells Cb. When detecting the voltage, the MUX 6 selects and outputs the voltage of the connection terminal PVn or the voltage of the connection terminal PSn, where the number suffixed to the target battery cell is generalized as n. For example, if the target battery cell is battery cell Cb12, the voltages of connection terminals PV12 and PS12 are output, if the target battery cell is battery cell Cb11, the voltages of connection terminals PV12 and PS11 are output, if the target battery cell is battery cell Cb2, the voltages of connection terminals PV2 and PS2 are output, and if the target battery cell is battery cell Cb1, the voltages of connection terminals PV1 and PS1 are output.

During voltage detection, the above-described operation is executed by the MUX 6, so that the voltages of the first output line Lo1 and the second output line Lo2 become detection target voltages that correspond to the voltages of the target battery cell. As a result, during voltage detection, the ADC 7 can perform A/D conversion on the detection target voltage corresponding to the voltages of the multiple battery cells Cb. The control unit 5 controls the operations of the MUX 6, the switches Sc1 to Sc4, and the ADC, and also functions as a detection control unit or a detection controller that detects the voltages of the multiple battery cells Cb in a time-division manner based on the digital signals output from the ADC.

In this way, the control unit 5 controls the operation of the MUX 6 so that the detection path corresponding to the target battery cell is connected to the ADC 7 during voltage detection. In the following description, the period during which the control unit 5 controls the operation of the MUX 6 in this manner will be referred to as a detection period. In this case, the control unit 5 can control the operation of the MUX 6 so that the voltages of the multiple battery cells Cb can be detected in a time-division manner in any order, that is, in any sequence.

In the above-described configuration, the following operation is performed during equalization in which a specific battery cell Cb is discharged in the equalization process. During equalization, the MUX 6 executes the above-mentioned second switching operation so that the equalization path corresponding to the battery cell to be discharged is connected to the ADC 7. In other words, the MUX 6 selects and outputs the voltage of the connection terminal PSn+1 and the voltage of the connection terminal PSn when the number appended to the end of the battery cell Cb as the detection target is generalized as n. For example, if the battery cell to be discharged is battery cell Cb12, the voltages of the connection terminals PS13 and PS12 are output, if the battery cell to be discharged is battery cell Cb11, the voltages of the connection terminals PS12 and PS11 are output, if the battery cell to be discharged is battery cell Cb2, the voltages of the connection terminals PS3 and PS2 are output, and if the battery cell to be discharged is battery cell Cb1, the voltages of the connection terminals PS2 and PS1 are output.

During equalization, the above-described operation is executed by the MUX 6, so that the voltages of the first output line Lo1 and the second output line Lo2 become voltages corresponding to the voltages of the battery cells to be discharged. Thereby, during equalization, the ADC 7 can perform A/D conversion of a voltage corresponding to the voltage of the battery cell to be discharged. The control unit 5 controls the operations of the MUX 6, the switches Sc1 to Sc4, and the ADC 7, and detects the voltage of the battery cell to be discharged based on the digital signal output from the ADC 7.

When executing a series of operations for detecting the voltages of each of the battery cells Cb in a time-division manner, the control unit 5 performs the following operations. In other words, when the potential difference between the voltage of the present target battery cell and the voltage of the target battery cell connected to the ADC 7 by the previous detection path becomes equal to or greater than a predetermined threshold value Vth, the control unit 5 provides a non-detection period in which it controls the operation of the MUX 6 so that the non-detection path is connected to the ADC 7 before detecting the voltage of the present target battery cell. The threshold value Vth can be set to any value that is higher than a value corresponding to the difference between the common-mode voltages of two adjacently connected battery cells Cb and less than the difference between the common-mode voltages of the two most distantly connected battery cells Cb.

In addition, when the potential difference between the voltage of the present target battery cell and the voltage at a specified location in the MUX 6 and ADC 7 in the initial state becomes equal to or greater than a threshold value Vth, the control unit 5 provides a non-detection period in which the operation of the MUX 6 is controlled so that a non-detection path is connected to the ADC 7 before detecting the voltage of the present target battery cell. The predetermined points in the MUX 6 and the ADC 7 may be any points that are connected to the detection path during voltage detection.

The control unit 5 can provide the non-detection period by one of the following two methods. As a first method, the control unit 5 can determine whether or not the above-mentioned potential difference is equal to or greater than the threshold value Vth, and provide a non-detection period based on the result of the determination. As a second method, the control unit 5 can provide a non-detection period in advance based on a result of a pre-determination of whether or not the above-mentioned potential difference is equal to or greater than the threshold value Vth.

In this case, the control unit 5 controls the operation of the MUX 6 so that the MUX 6 performs the first switching operation during the non-detection period. Specifically, the control unit 5 controls the operation of the MUX 6 during the non-detection period so that the MUX 6 performs a first switching operation to switch the path so that the low potential side terminal of the present target battery cell is connected to the ADC 7. In other words, during the non-detection period, the control unit 5 turns on only the switch SS of the switches SS1 to SS13 of the MUX 6 that corresponds to the present target battery cell. Furthermore, the control unit 5 turns on all of the switches Sc1 to Sc4 during the non-detection period. Such operations during the non-detection period are different from the operations that the battery monitoring IC 3 should normally perform, such as operations for detecting the voltage of the battery cell Cb, and therefore will be referred to as “idling” in the following description.

### Specific Example of a Series of Operations Performed During Voltage Detection

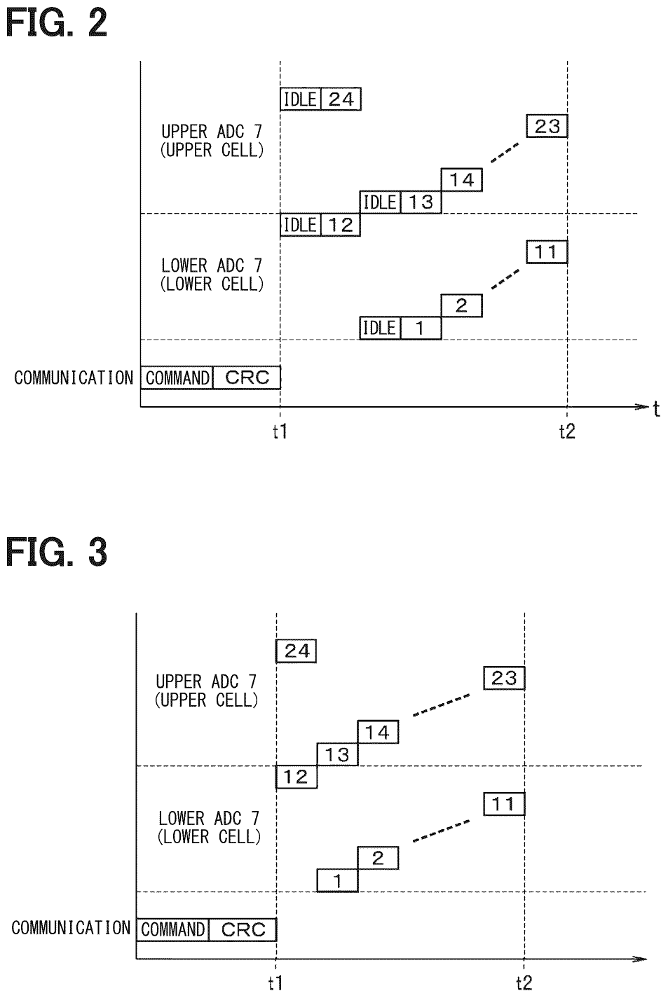

Next, a specific example of a series of operations performed by the battery monitoring IC 3 when detecting the voltages of the battery cells Cb in a time-division manner, that is, when detecting voltages, will be described with reference to FIG. 2. In the following description and in FIG. 2, when it is necessary to distinguish between the configurations corresponding to upper cells and the configurations corresponding to lower cells, the distinction will be made by adding “upper” and “lower” at the beginning, respectively. In addition, in FIG. 2, the battery cells Cb1 to Cb24 are abbreviated to the reference numerals appended to the end of the cells, and “idling” may also be referred to as “idle”.

As shown in FIG. 2, a series of operations related to voltage detection starts at time t1 when a series of operations related to communication ends. This series of operations is executed until time t2. In this case, the control unit 5 controls various operations so that the upper ADC 7 executes A/D conversion of the detection target voltage corresponding to the voltage of the upper cell in the order of “battery cell Cb23 →battery cell Cb24→battery cell Cb13→battery cell Cb14→ . . . →battery cell Cb23. In this case, the control unit 5 controls various operations so that the lower ADC 7 executes A/D conversion of the detection target voltage corresponding to the voltage of the upper cell in the order of battery cell Cb12→battery cell Cb1→battery cell Cb2 → . . . →2 battery cell Cb11.

In the initial state before the upper ADC 7 performs A/D conversion on the first battery cell Cb24 in the above-mentioned sequence, the voltages at predetermined points in the MUX 6 and ADC 7 are approximately zero. When voltage detection of the leading battery cell Cb24 is performed from such an initial state, the potential difference between the voltage of the battery cell Cb24, which is the present target battery cell, and the voltage at a predetermined location in the MUX 6 and ADC 7 in the initial state, becomes equal to or greater than the threshold value Vth. Therefore, the control unit 5 executes idling before the upper ADC 7 performs A/D conversion on the first battery cell Cb24 in the above sequence.

Furthermore, in the initial state before the lower ADC 7 performs A/D conversion on the first battery cell Cb12 in the above-mentioned sequence, the voltages at predetermined points in the MUX 6 and ADC 7 are approximately zero. When voltage detection of the leading battery cell Cb12 is performed from such an initial state, the potential difference between the voltage of the battery cell Cb12, which is the present target battery cell, and the voltage at a predetermined location in the MUX 6 and ADC 7 in the initial state, becomes equal to or greater than the threshold value Vth. Therefore, the control unit 5 executes idling before the upper ADC 7 performs A/D conversion on the first battery cell Cb12 in the above sequence.

When the upper ADC 7 performs A/D conversion on the battery cell Cb13, the potential difference between the common voltage of battery cell Cb13, which is the present target battery cell, and the common voltage of the battery cell Cb24, which is the target battery cell connected to the ADC 7 by the previous detection path, becomes greater than or equal to the threshold value Vth. Therefore, the control unit 5 executes idling before the upper ADC 7 performs A/D conversion on the battery cell Cb13.

When the lower ADC 7 performs A/D conversion on the battery cell Cb1, the potential difference between the common voltage of battery cell Cb1, which is the present target battery cell, and the common voltage of the battery cell Cb12, which is the target battery cell connected to the ADC 7 by the previous detection path, becomes greater than or equal to the threshold value Vth. Therefore, the control unit 5 executes idling before the upper ADC 7 performs A/D conversion on the battery cell Cb1. In this embodiment, the non-detection period during which the idle rotation is performed is, for example, about 7 microseconds (us), which is sufficiently short compared to the entire operation time of about 8 milliseconds (ms). In this way, the control unit 5 controls the operations of the MUX 6 and the ADC 7 so that the non-detection period is shorter than the detection period.

According to the present embodiment described above, the following effects are obtained. When the potential difference between the voltage of the present target battery cell and the voltage of the target battery cell connected to ADC 7 by the previous detection path or the voltage of a specified location in the MUX 6 and ADC 7 in the initial state becomes equal to or greater than a threshold value Vth, the control unit 5 provides a non-detection period in which the operation of the MUX 6 is controlled so that a non-detection path having a smaller time constant than the detection path is connected to ADC 7 before detecting the voltage of the present target battery cell.

According to this configuration, a non-detection period is provided when the common voltage of the battery cell Cb to be detected fluctuates significantly, such as during the initial voltage detection or when the detection target switches from the top battery cell Cb24, Cb12 to the bottom battery cell Cb13, Cb1. Therefore, according to the above configuration, in such a case, the electric charge that would cause an error in voltage detection is discharged via the non-detection path, thereby suppressing the occurrence of voltage detection errors. In this case, the non-detection path has a smaller time constant than the detection path, so the time required for discharging the charge, and therefore the non-detection period, can be kept relatively short. Therefore, according to this embodiment, it is possible to obtain the adventageous effect of improving the accuracy of voltage detection while suppressing an increase in the overall detection time required to detect the voltages of the multiple battery cells Cb.

The effect obtained by this embodiment will be further clarified by comparing with the comparison example corresponding to the configuration of the conceivable technique. Therefore, a comparative example will be described, and then the comparative example will be compared with this embodiment. The comparative example has a similar configuration to this embodiment, but the contents of control by the control unit 5 are different from those of this embodiment. In the comparative example, as shown in FIG. 3, in the series of operations performed by the battery monitoring IC 3 when detecting the voltages of each of the multiple battery cells Cb in a time-division manner, no non-detection period is provided, and idling is not performed.

Therefore, in the comparative example, when voltage detection is performed on the first battery cells Cb24 and Cb12 from the initial state, and when voltage detection is performed on the battery cells Cb13 and Cb1, a current that becomes an error source flows in the filter 4 due to the discharge of the electric charge stored in the internal parasitic capacitance of the MUX 6, ADC 7, etc., and as a result, a voltage detection error occurs. The occurrence of such detection errors will now be described in detail with reference to a specific example. It is assumed here that the voltage detection of the battery cell Cb1 is performed after the voltage detection of the battery cell Cb12 is performed.

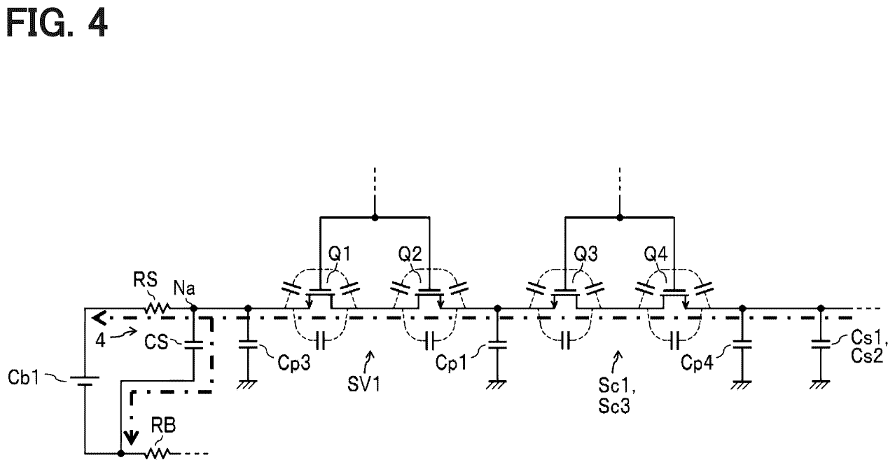

In this case, the fluctuation in the common voltage of the battery cell Cb to be detected is extremely large, at approximately 60V. As shown in FIG. 4, when detecting the voltage of the battery cell Cb1, the path from the battery cell Cb1 to the ADC 7 includes MOS transistors Q1 and Q2 that are included in the switch SV1 of the MUX 6, and MOS transistors Q3 and Q4 that are included in the switch Sc1 or Sc3. In each of the MOS transistors Q1 to Q4, a MOS capacitance exists between the gate and source, between the gate and drain, and between the drain and source.

In addition, there is a parasitic capacitance Cp3 due to wiring between the filter 4 and MUX 6, a parasitic capacitance Cp1 due to wiring between the MUX 6 and the switch Sc1 or Sc3, and a parasitic capacitance Cp4 due to wiring between the switch Sc1 or Sc3 and the capacitor Cs1 or Cs2 and the ADC 7. In the following, such a parasitic capacitance will be referred to as an internal node parasitic capacitance. In this case, a very large common voltage fluctuation causes charges to be discharged from the internal node parasitic capacitances and the MOS capacitances. As a result, a current flows through a path indicated by a dashed arrow in FIG. 4, that is, a path that includes a detection path that passes through resistor RS and capacitor CS of filter 4, resulting in a voltage detection error due to a voltage drop ΔV1 across resistor RS.

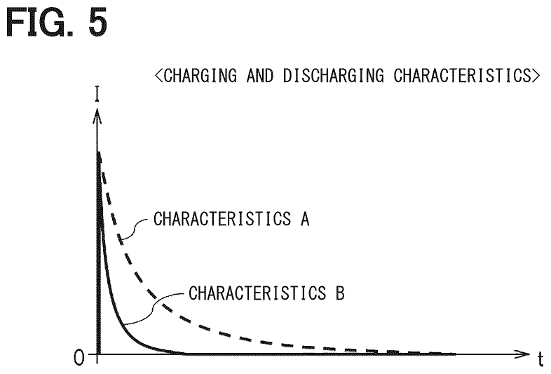

The charging/discharging characteristics of a path including the detection path that passes through the filter 4 are determined by the filter constant of the filter 4, which is an RC filter. Since the filter 4 is required to remove noise of a relatively low frequency that is superimposed on the battery cell Cb, the resistance value of the resistor RS and the capacitance value of the capacitor CS are set to relatively large values. Therefore, as shown by the broken line in FIG. 5, the charging/discharging response during the above-mentioned discharge becomes very slow. In FIG. 5, the vertical axis represents the charge/discharge current I, and the horizontal axis represents time t. Therefore, in the comparative example, the discharge of the internal node parasitic capacitance and the MOS capacitance is delayed due to the action of the filter 4, resulting in a large voltage detection error.

In contrast, in this embodiment, as shown in FIG. 2, in the series of operations performed by the battery monitoring IC 3 when detecting the voltage of each of the multiple battery cells Cb in a time-division manner, a non-detection period is provided, and idling is performed. Therefore, in this embodiment, when voltage detection is performed on the first battery cells Cb24 and Cb12 from the initial state, and when voltage detection is performed on the battery cells Cb13 and Cb1, idling is performed and the internal charge is discharged before performing these voltage detections. As a result, in this embodiment, a current that may cause an error is prevented from flowing through the filter 4, and as a result, the occurrence of voltage detection errors is suppressed.

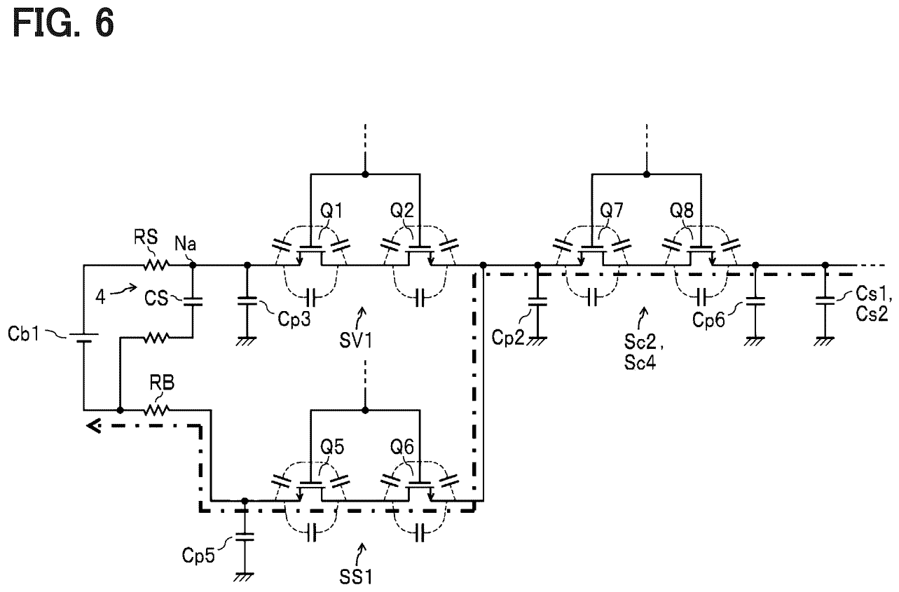

The reason why the occurrence of detection errors is thus suppressed will be described in detail below with reference to a specific example. It is assumed here that idling is performed after voltage detection of battery cell Cb12 and before voltage detection of battery cell Cb1 is performed. In this case as well, the fluctuation in the common voltage of the battery cell Cb being detected is extremely large, at approximately 60V. As shown in FIG. 6, in the path from the battery cell Cb1 to the ADC 7 when idling is being performed, there are MOS transistors Q5 and Q6 included in the switch SS1 of the MUX 6, and MOS transistors Q7 and Q8 included in the switch Sc2 or Sc4. In each of the MOS transistors Q5 to Q8, a MOS capacitance exists between the gate and source, between the gate and drain, and between the drain and source.

In addition, there is a parasitic capacitance Cp5 due to wiring between the filter 4 and MUX 6, a parasitic capacitance Cp2 due to wiring between the MUX 6 and the switch Sc2 or Sc4, and a parasitic capacitance Cp6 due to wiring between the switch Sc2 or Sc4 and the capacitor Cs1 or Cs2 and the ADC 7. Again, very large common voltage fluctuations cause charge to be discharged from internal node parasitic capacitances and MOS capacitances. As a result, a current flows through a path indicated by an arrow with a dashed line in FIG. 6, that is, a path including a non-detection path that does not pass through the resistor RS and capacitor CS of the filter 4 but passes through the equalization resistor RB.

Also in this case, a voltage detection error occurs due to the voltage drop ΔV2 across resistor RB. However, since the resistance value of resistor RB is much smaller than the resistance value of resistor RS, the voltage drop ΔV2 is much smaller than the voltage drop ΔV1. As a result, the voltage detection error is also kept very small. The charging/discharging characteristics of a path including a non-detection path that does not pass through filter 4 are such that there is no resistor with a relatively large resistance value or a capacitor with a relatively large capacitance value on that path, and therefore the charging/discharging response during the above-mentioned discharge is very fast, as shown by characteristic B indicated by the solid line in FIG. 5. Therefore, in this embodiment, by passing a current through the equalization resistor RB, the internal node parasitic capacitance and the MOS capacitance are discharged quickly, and the voltage detection error is suppressed to a small value.

In this embodiment, one MUX 6 is used to select either the detection path or the non-detection path as the path connected to the ADC 7. In this way, since switching to the non-detection path can also be performed using the MUX 6 originally provided in the battery monitoring IC 3, an increase in circuit size accompanying the addition of a non-detection period is suppressed. In this embodiment, the control unit 5 controls the operations of the MUX 6 and the ADC 7 so that the non-detection period is shorter than the detection period. In this way, it is possible to improve the accuracy of voltage detection while minimizing the increase in the overall detection time caused by adding a non-detection period in order to suppress voltage detection errors.

The control unit 5 determines whether or not the above-mentioned potential difference is equal to or greater than a threshold value Vth, and can provide a non-detection period based on the result of the determination. In this way, it is possible to add the minimum non-detection period required to obtain the desired voltage detection accuracy, and as a result, the increase in the overall detection time can be further suppressed. Furthermore, in this way, even if the sequence for detecting the voltages of the multiple battery cells Cb is not predetermined and changes, it is possible to add non-detection periods at appropriate timing. Furthermore, the control unit 5 can set a non-detection period in advance based on the result of a pre-determination of whether or not the above-mentioned potential difference is equal to or greater than the threshold value Vth. In this way, the complexity of the control by the control unit 5 caused by adding the non-detection period can be kept as small as possible.

### Modified Example regarding the Control Contents by the Control Unit 5 During the Non-Detection Period

The control unit 5 controls the operation of the MUX 6 so that the MUX 6 performs the first switching operation during the non-detection period, but it can also control the operation of the MUX 6 so that the MUX 6 performs the second switching operation. Specifically, the control unit 5 can also control its operation so that during the non-detection period, the MUX 6 performs a second switching operation in which the MUX 6 switches the path so that the equalization path corresponding to the present target battery cell is connected to the ADC 7. In this modified example, as in the present embodiment, electric charges that are a cause of errors in voltage detection are discharged via an equalization path that corresponds to a non-detection path, thereby suppressing the occurrence of voltage detection errors. Also in this case, since the equalization path has a smaller time constant than the detection path, the time required for discharging the electric charge can be kept relatively short.

### Modified Example Related to Path Switching Unit

In this embodiment, the path switchover unit may have one MUX 6, and this one MUX 6 is used to select either the detection path or the non-detection path as the path to be connected to the ADC 7. However, the path switchover unit may have two MUXs, and use these two MUXs to select either the detection path or the non-detection path as the path to be connected to the ADC 7.

Specifically, the path switchover unit may include a first MUX having switches SV corresponding to the connection terminals PV1 to PV12, and a second MUX having switches SS corresponding to the connection terminals PS1 to PS13. The switch SV of the first MUX and the switch SS of the second MUX are connected in such a manner that they can perform switching similarly to the switches SV and SS of the MUX 6. Even with this modified example, the path connected to the ADC 7 can be switched as in the present embodiment, and therefore the same effects as in the present embodiment can be obtained.

### Second Embodiment

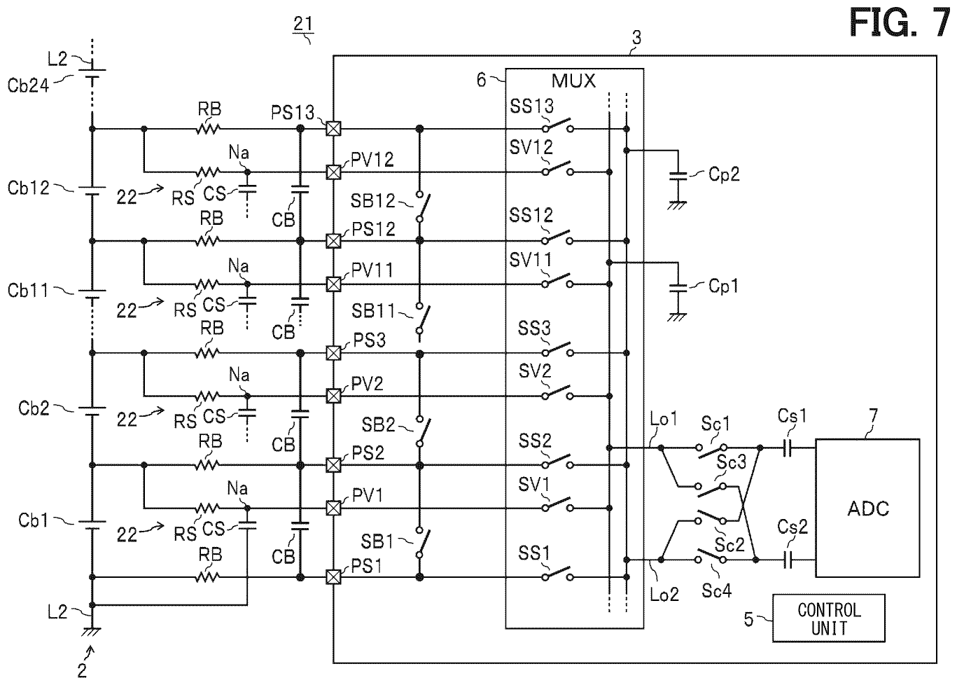

Hereinafter, a second embodiment will be described with reference to FIG. 7. As shown in FIG. 7, a battery monitoring device 21 according to this embodiment differs from the battery monitoring device 1 according to the first embodiment in the configuration of external elements. The battery monitoring device 21 includes a filter 22 instead of the filter 4.

The filter 22, like the filter 4, is an LPF having a resistor RS and a capacitor CS. However, the filter 22 is different from the filter 4 in the connection form of the low potential terminal of the capacitor CS. That is, although some of the illustration is omitted, the low potential terminals of the capacitors CS corresponding to the battery cells Cb1 to Cb24 are commonly connected and are also connected to the DC power supply line L2.

The battery monitoring device 21 includes a capacitor CB provided corresponding to each of the battery cells Cb. The capacitor CB is included in a discharge circuit together with the resistor RB and the equalization switch SB, and therefore the capacitance value thereof is much smaller than the capacitance value of the capacitor CS included in the filter 22. A specific connection form of the equalization switch SW is described as follows.

That is, the capacitor CB12 corresponding to the battery cell Cb12 is connected between the connection terminal S13 and the connection terminal S12. Although some parts are not shown in the drawing, the capacitor CB11 corresponding to the battery cell Cb11 is connected between the connection terminal PS12 and the connection terminal PS11. The capacitor CB2 corresponding to the battery cell Cb2 is connected between the connection terminal PS3 and the connection terminal PS2. The capacitor CB1 corresponding to the battery cell Cb1 is connected between the connection terminal PS2 and the connection terminal PS1.

The detection path in the battery monitoring device 21 configured as above is the same as the detection path in the battery monitoring device 1 according to the first embodiment. Moreover, the equalization path in the battery monitoring device 21 configured as described above is the same as the equalization path in the battery monitoring device 1 of the first embodiment. Therefore, in the battery monitoring device 21 as well, the equalization path corresponds to a non-detection path having a smaller time constant than the detection path.

In this embodiment, the control unit 5 controls the operation of the MUX 6 so that the MUX 6 performs the second switching operation during the non-detection period. Specifically, the control unit 5 controls the operation so that during the non-detection period, the MUX 6 executes a second switching operation to switch the path so that the equalization path corresponding to the present target battery cell is connected to the ADC 7. In this embodiment, as in the first embodiment, electric charges that cause errors in voltage detection are discharged via the equalization path that corresponds to the non-detection path, thereby suppressing the occurrence of voltage detection errors. Also in this case, since the equalization path has a smaller time constant than the detection path, the time required for discharging the electric charge can be kept relatively short.

### Other Embodiments

The present disclosure is not limited to the embodiments that have been described above and illustrated in the drawings, but can arbitrarily be modified, combined, or expanded without departing from the gist of the present disclosure. The numerical values and the like illustrated in each of the above embodiments are merely examples, and the present disclosure is not limited thereto.

The filter connected in series to the detection path is not limited to the filters 4 and 22 described in the above embodiments, and filters of various configurations, such as a pi-shaped RC filter or an LC filter, can be used. The non-detection path is not limited to the equalization path or a part of the equalization path described in each of the above embodiments, and may be any path having a smaller time constant than the detection path.

Although the present disclosure has been made in accordance with the embodiments, it is understood that the present disclosure is not limited to such embodiments and structures. The present disclosure encompasses various modifications and variations within the scope of equivalents. Various combinations or forms as well as other combinations or forms including only one element, one or more elements, or fewer elements fall within the scope or the concept of the present disclosure.

What is claimed is:

1. A battery monitoring device configured to monitor a battery pack in which battery cells are connected in series, the battery monitoring device comprising:
a voltage detector configured to detect respective voltages of the battery cells through a detection path that is connected to both ends of each of the battery cells; and
a filter configured to be adapted to each of the battery cells, the filter connected in series to the detection path, wherein
the voltage detector includes:
an analog-to-digital converter configured to execute analog-to-digital conversion on target detection voltages corresponding to the respective voltages of the battery cells;
a path switchover unit configured to switch a path connected to the analog-to-digital converter; and
a detection controller configured to
execute control of the path switchover unit and the analog-to-digital converter, and
detect the respective voltages of the battery cells in a time-division manner, based on a digital signal output from the analog-to-digital converter,
the detection controller is configured to:
connect the detection path, which corresponds to a target battery cell being a battery cell to be detected among the battery cells, to the analog-to-digital converter in a case of detecting a voltage of the target battery cell, in the control of the path switchover unit; and
set a non-detection period during which a non-detection path is connected to the analog-to-digital converter before detecting a first voltage, in a case where a potential difference between the first voltage and a second voltage is equal to or higher than a predetermined threshold,
the non-detection path has a smaller time constant than the detection path,
the first voltage is a voltage of a present target battery cell being a battery cell to be detected in a present instance among the battery cells,
the second voltage is either
a voltage of a previous target battery cell being a battery cell connected to the analog-to-digital converter by the detection path in a previous instance among the battery cells, or
a voltage at a predetermined point in the path switchover unit and the analog-to-digital converter in an initial state, and
the path switchover unit includes a single multiplexer configured to select one of the detection path and the non-detection path as a selected path connected to the analog-to-digital converter.

2. The battery monitoring device according to claim 1, wherein
the path switchover unit is configured to operate in a first switching operation to connect only one of both ends of the target battery cell to the analog-to-digital converter, and
the detection controller is configured to control the path switchover unit to operate in the first switching operation in the non-detection period.

3. The battery monitoring device according to claim 1, wherein
the detection controller is configured to set the non-detection period shorter than a detection period, in the control of the path switchover unit and the analog-to-digital converter, and
the detection period is a period during which the path switchover unit is controlled to detect the voltage of the target battery cell.

4. The battery monitoring device according to claim 1, wherein
the path switchover unit is configured operate in a second switching operation to connect an equalization path to the analog-to-digital converter,
the equalization path is a path that causes the battery cells to discharge, and
the detection controller is configured to control the path switchover unit to operate in the second switching operation in the non-detection period.

5. The battery monitoring device according to claim 1, wherein
the detection controller is configured to set the non-detection period based on a result of determining whether or not the potential difference is equal to or higher than the predetermined threshold.

6. The battery monitoring device according to claim 1, wherein
the detection controller is configured to preliminarily set the non-detection period, based on a result of preliminarily determining whether or not the potential difference is equal to or higher than the predetermined threshold.
